(19) United States
(12) Patent Application Publication
(10) Pub. No.: US 2026/0118750 A1
(43) Pub. Date: Apr. 30, 2026

(54) SYSTEM AND METHOD FOR PHOTOMASK DATABASE INSPECTION USINGMODEL BASED LAYOUT RENDERING

(71) Applicant: PHOTRONICS, INC., Brookfield, CT (US)

(72) Inventors: Mohamed Ramadan, Corona, CA (US); Christopher Progler, Plano, TX (US); Jongmin Kim, Meridian, ID (US)

(21) Appl. No.: 19/367,494

(22) Filed: Oct. 23, 2025

Related U.S. Application Data
(60) Provisional application No. 63/711,306, filed on Oct. 24, 2024.

(51) Int. Cl. G03F 1/84; G06F 30/31

(52) U.S. Cl. CPC G03F 1/84; G06F 30/31

(57) ABSTRACT

A method for detecting photomask defect including rendering a simulated photomask contour based on photomask design data, manufacturing a photomask based on the photomask design data, and performing an inspection for photomask defects by comparing the rendered simulated photomask contour with the manufactured photomask.

### RELATED APPLICATIONS

This application claims priority to and the benefit of U.S. Provisional Patent Application No. 63/711,306, filed Oct. 24, 2024 and entitled SYSTEM AND METHOD FOR PHOTOMASK DATABASE INSPECTION USING MODEL BASED LAYOUT RENDERING, the contents of which are incorporated herein by reference in their entirety.

### TECHNICAL FIELD

The present disclosure generally relates to manufacturing of photomasks, and more particularly to photomask inspection tools and techniques.

### BACKGROUND

Photomask inspection tools are essential in a semiconductor manufacturing process to ensure that photomasks, which are used to transfer circuit patterns onto silicon wafers, are free from defects. The types of defects that might be identified during inspection include, for example, etch blocks, pin holes, clear extensions, dark extensions, size differences, and missing patterns, to name a few. There are essentially two kinds of inspection paradigms, one being die-to-die comparison and the other being die-to-database comparison.

Typical masks have more than one chip on them, and a very straightforward way to inspect them is to compare one die to the next. An inspection tool using a high-resolution camera looks at a picture of one region, looks at a picture of the same region on the different die and compares the differences. Any difference might represent a defect because all images should be identical.

In the case of one or less chips per mask, die-to-die comparison is not possible, so that die-to-database inspection must be used. Die-to-database inspection involves comparison of the actual mask to a database of what the design data is supposed to look like. Die-to-database comparisons are significantly more complicated and very compute-intensive compared with die-to-die comparisons.

Advanced resolution enhancements techniques such as those employing curvilinear layout geometries, can severely impact the speed and efficiency of back-end mask steps including inspection, defect disposition and repair. For example, when an aggressive mask pattern design is presented for die to database inspection, the fabricated mask may be quite different than the design due to pattern fidelity losses (e.g., line end shortening, LER, corner rounding) in the mask making process. This can result in large numbers of nuisance defects, false calls and a general inability to distinguish important defects from the inconsequential. Even with smart automatic defect classification systems and skilled operators, sorting defects for further processing can be a daunting task. For layouts with strong curvilinear shapes, the problem is compounded due to mask pattern formation and inspection limitations.

There is an ongoing need for a more effective inspection technique that addresses the problems associated with identifying defects in photomasks, particularly photomasks that implement advanced resolution enhancement techniques, such as curvilinear layout geometries.

### SUMMARY OF THE INVENTION

An object of the present invention is to provide a system and method for more effectively inspecting a photomask for defects, particularly where the photomask implements advanced resolution techniques, such as curvilinear geometries.

Another object of the present invention is to provide a system and method for inspecting a photomask for defects that involves a modification of the conventional die-to-database technique in which the perfect mask input database is substituted with a simulated mask rendering of the database that accurately reflects the database transformation that happens during actual mask manufacturing.

A method according to an exemplary embodiment of the present invention comprises: (A) rendering a simulated photomask design database contour based on the starting photomask design and photomask manufacturing data; (B) manufacturing a photomask based on the photomask design data; and (C) performing an inspection for photomask defects by comparing the rendered simulated photomask contour with the manufactured photomask

In an exemplary embodiment, step (A) comprises: 1) generating a photomask manufacturing process model based on the photomask design data, critical structures of the photomask and high resolution measured mask images such as those from a scanning electron microscope (SEM) image of the critical structures, the photomask process model comprising data associated with simulated photomask contours; 2) applying the photomask manufacturing process model to the design database to create a simulated rendering of the database.

In an exemplary embodiment, step (A)(1) is performed using a model generated by either an Electronic Design Automation (EDA) tool or with a model generation engine purpose built for producing accurate mask model contours.

In an exemplary embodiment, the photomask comprises curvilinear regions.

In an exemplary embodiment, the photomask comprises rectilinear regions.

In an exemplary embodiment, a method of manufacturing a photomask comprises a step of inspecting the photomask using the above-described process steps.

A system according to an exemplary embodiment of the present invention comprises: one or more computer processors; and non-transitory computer-readable memory having stored thereon instructions which, when executed by the one or more computer processors, cause the one or more computer processors to carry out a method comprising: (A) rendering a simulated photomask contour based on photomask design data; (B) manufacturing a photomask based on the photomask design data; and (C) performing an inspection for photomask defects by comparing the rendered simulated photomask contour with the manufactured photomask.

In an exemplary embodiment, step (A) comprises: 1) generating a photomask process model based on the photomask design data, critical structures of the photomask and known scanning electron microscope (SEM) images of the critical structures, the photomask process model comprising data associated with simulated photomask contours; 2) refining the process model by comparing the data associated with the simulated photomask contours with a singular or stitched together image of the SEM images; and 3) performing a forward simulation of the simulated photomask contours to render the photomask contours.

In an exemplary embodiment, step (A)(1) is performed using an Electronic Design Automation (EDA) tool.

In an exemplary embodiment, the photomask comprises curvilinear regions.

In an exemplary embodiment, the photomask comprises rectilinear regions.

### BRIEF DESCRIPTION OF THE DRAWINGS

Exemplary embodiments of the present invention will be described with references to the accompanying figures, wherein:

FIG. 1 is a simplified diagram of a photomask inspection tool;

FIG. 2 is a flow chart showing a process for photomask inspection according to an exemplary embodiment of the present invention;

FIG. 3 is a flow chart showing a process for rendering a mask contour using a mask process model forward simulation according to an exemplary embodiment of the present invention;

FIGS. 4A-4C shows an example of the primary parts of a mask model including the original design database, a high resolution SEM image of the fabricated mask from this database and an overlay of a model built to represent the mask process overlayed onto the fabrication mask;

FIGS. 5A and 5B shows examples of original database image and the simulation rendered database image which will be applied in the mask inspection step in the current invention; and

FIGS. 6A and 6B illustrate the comparison between a conventional photomask inspection technique and a photomask inspection technique according to an exemplary embodiment of the present invention.

### DETAILED DESCRIPTION

Systems and methods in accordance with exemplary embodiments of the present invention are directed to a photomask inspection tool in which simulated mask rendering generated based on a database of photomask design data is compared to a photomask die to determine defects in the photomask die. By substituting the perfect mask input database with a simulated mask rendering of the database that represents specifically what will happen to the design during photomask manufacturing, a die to database inspection can proceed on a far more realistic basis greatly improving the quality of the inspected output.

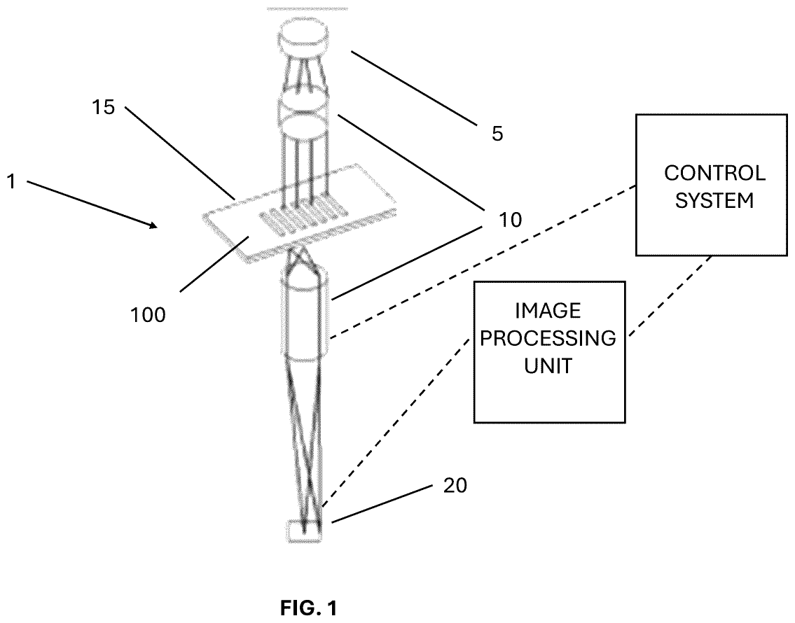

FIG. 1 is a simplified diagram of a photomask inspection tool, generally designated by reference number 1, according to an exemplary embodiment of the present invention. The tool 1 includes an illumination system 5, an optical system 10, a stage 15, a detector 20, an image processing unit 25 and a control system 30. The illumination system 5 provides a light source to illuminate a photomask 100 held on the stage 15. The light source may generate light at wavelengths, such as, for example, 13.5 nm, 193 nm, 213 nm, and 248 nm, to name a few. The optical system 10 includes lenses and mirrors to focus the light onto the photomask 100 and capture the reflected or transmitted light. The detector 20 captures the light and converts it into an image. The detector 20 may be, for example, a CCD (charge-coupled device) camera. The image processing unit 25 is configured to analyze the captured images to detect defects, for example by comparing the captured image to a simulated mask rendering generated based on a photomask design database. The control system may include a computer processor and memory, where computer-readable instructions are stored on the memory that, when carried out by the processor, result in operation of the tool and processing of the data.

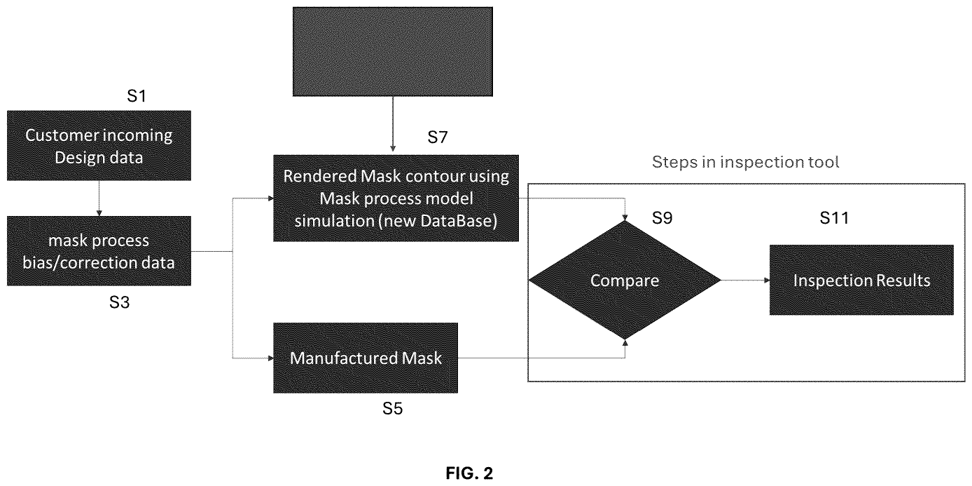

FIG. 2 is a flow chart showing a process for photomask inspection according to an exemplary embodiment of the present invention. In step S1 of the process, customer photomask design data is received by a photomask manufacturer. In this regard, a photomask is typically required to manufacture a semiconductor and other devices. As is often the case, a semiconductor manufacturer will out source the task of manufacturing a photomask to a company which specializes in the manufacture of photomasks. Such semiconductor manufacturers, however, must first design the photomask to be manufactured. In this regard, the semiconductor manufacturer will develop certain data and specifications to be provided to the photomask manufacturer. More specifically, the semiconductor manufacturer (hereinafter, “the customer”) will generate on its computer: (1) pattern data; and (2) other specific information relating to the specific job, which are often provided in an industry standard format such as the SEMI P-10 form (resulting in a SEMI Specification), but may be provided in other custom formats.

Jobdeck processing is then performed on the photomask design data to carry out photomask processing and inspection (Step S3). Jobdeck processing refers to the method by which instructions are transferred to and processed by lithography tools (e.g., E-beam and laser beam) and inspection equipment (e.g., KLA or Orbot). In the case of lithography jobdeck processing, certain instructions which are needed to write a pattern on a photomask blank are extracted from the SEMI Specification and stored in a jobdeck. These extracted jobdeck instructions are then processed for use with the lithography tools. These instructions indicate the location on the photomask in which the various patterns are to be placed, as well as other functions to be performed by the particular tool including but not necessarily limited to controlling exposure, scaling of patterns, and tone, to name a few. Certain data in the SEMI Specification may be adjusted and/or corrected to account for variables, such as, for example, critical dimensions, biasing information, and pellicle type, to name a few.

In Step S5, a photomask is manufactured based on the photomask processing jobdeck instructions. As known in the art, the photomask manufacturing steps involve the use of photolithographic tools and involves any number of sub-steps, such as, for example, deposition, etching and exposing, to name a few. Generally, after the manufacturing of the mask, the mask patterns produced are reasonable representations of the original design data but never an exact match.

Typically, with respect to inspection jobdeck processing, the relevant SEMI Specification instruction is extracted from and arranged for use by inspection equipment. The extracted SEMI Specification instructions for the inspection equipment are arranged and formatted such that the inspection equipment can inspect a processed photomask for defects (e.g., die-to-data comparison) and contaminations (i.e., cleanliness).

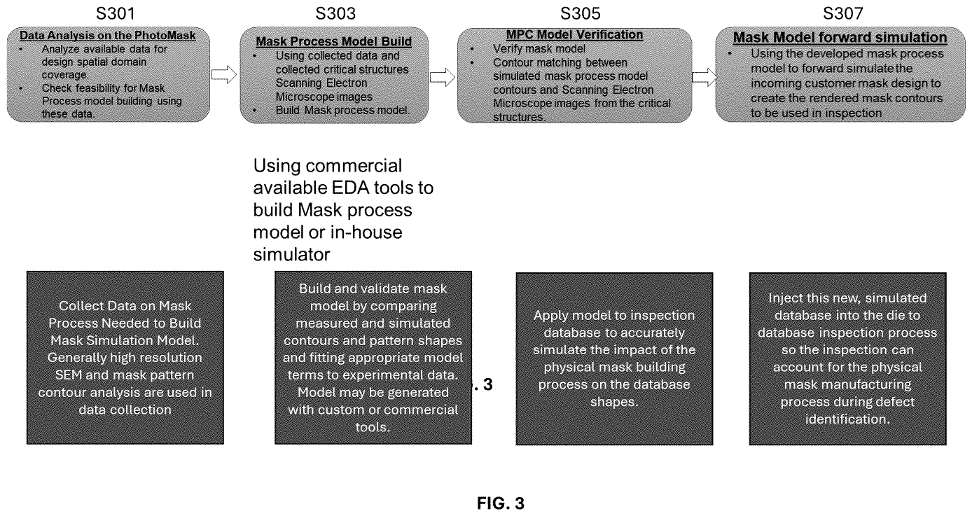

However, rather than performing conventional inspection jobdeck processing, in exemplary embodiments of the present invention, a mask contour is rendered using a mask process model forward simulation (Step S7). In this regard, FIG. 3 is a flow chart showing a process for rendering a mask contour using a mask process model forward simulation according to an exemplary embodiment of the present invention. In step S301 of the process, the mask data is checked to determine whether the data is viable and whether enough data is present to simulate the mask. This step may involve checking whether the mask data violates any rules, such as, for example, rules associated with critical structures and process flow, to name just two. In step S303 of the process, a mask process model is generated using the mask data, critical structures, and prior known SEM images of critical structures. In exemplary embodiments, the mask process model incorporates simulated mask contours. Generation of the mask process model may be performed using commercially available Electronic Design Automation (EDA) tools. In step S305 of the process, the mask process model is verified by comparing the simulated contours with the SEM image using contour matching. In step S307, the simulated contours of the verified mask process model are used in a forward simulation to render the mask contours of the model simulated mask to be used in the inspection process.

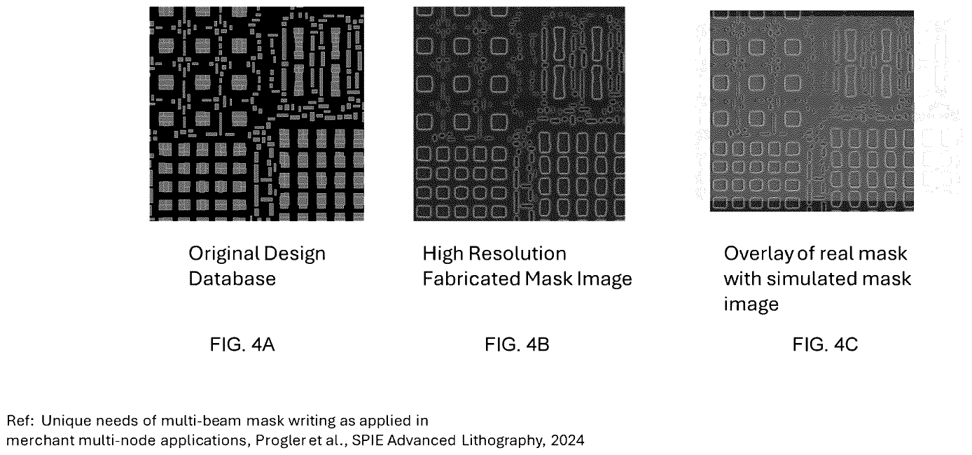

FIGS. 4A-4C shows an example of the primary parts of a mask model including the original design database (FIG. 4A), a high resolution SEM image of the fabricated mask from this database (FIG. 4B) and an overlay of a model built to represent the mask process overlayed onto the fabrication mask (FIG. 4C).

Turning back to FIG. 2, after rendering of the simulated mask contours, the inspection process continues in step S9 with a comparison between the simulated mask contour and manufactured mask. The inspection results, which may include detected errors, are output at step S11.

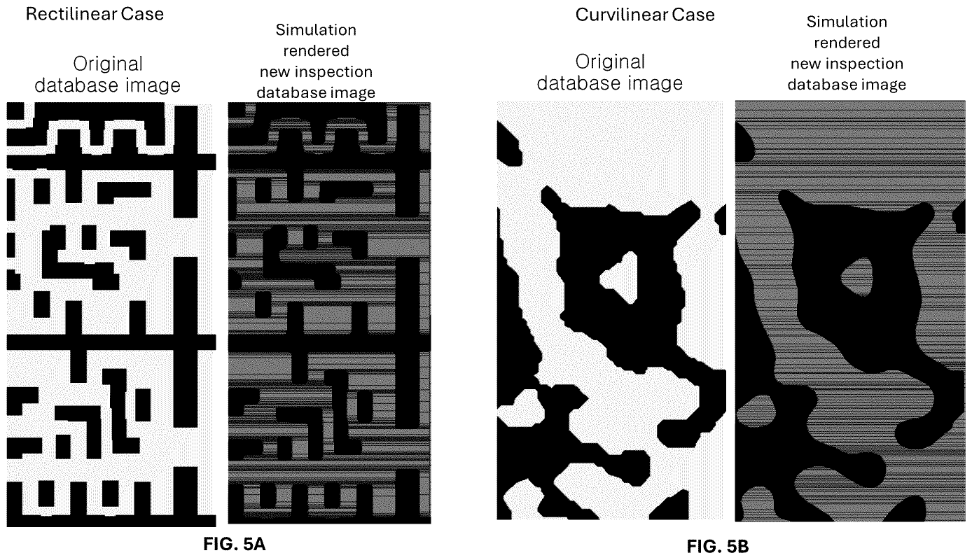

FIGS. 5A and 5B shows examples of original database images and simulation rendered database images which are applied in the mask inspection step. Specifically, FIG. 5A shows a rectilinear example of an original database image and simulation rendered database image, and FIG. 5B shows a curvilinear example of an original database image and simulation rendered database image.

The model simulated mask and lithographic simulation of the model simulated mask more accurately predicts the lithographic output of the SEM mask compared to the prediction offered by the GDS mask. This allows for modification of the model simulated mask to improve the lithographic process. For example, errors can be more easily detected using the model simulated mask and corrected by modifying the model simulated mask.

The following example illustrates advantages of exemplary embodiments of the present invention.

### Example

Rectilinear features on a photomask were inspected with normal design process of record (PoR) versus rendered/predicted mask contour using mask model forward simulation. Inspect A small curvilinear area of the photomask was also inspected with normal design PoR versus rendered/predicted mask contour using mask model forward simulation. Accuracy and reported defects were compared using different inspection sensitivity.

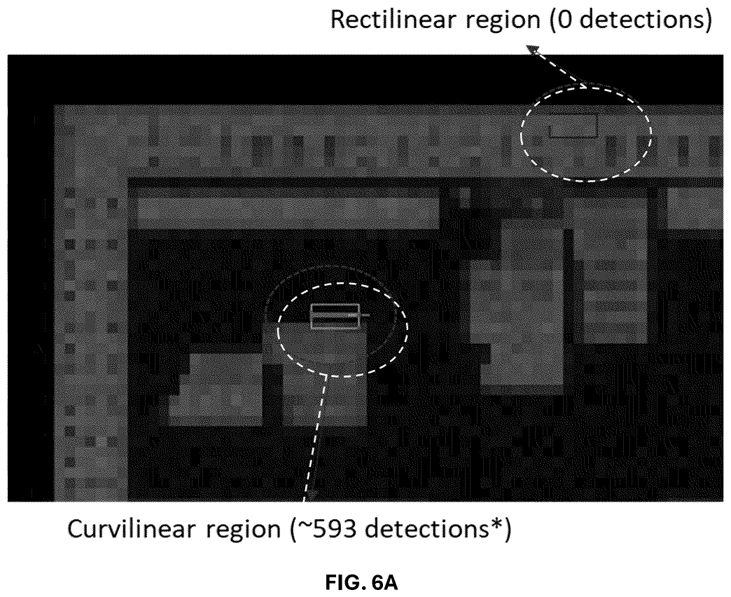

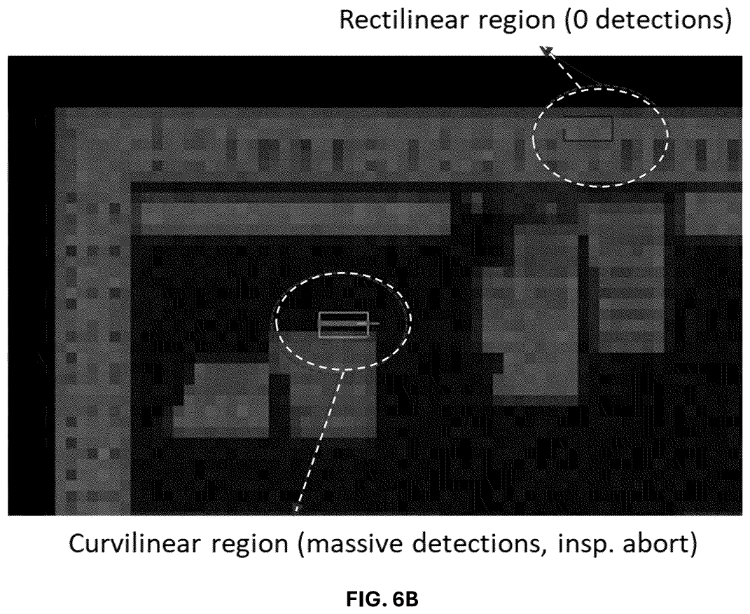

FIGS. 6A and 6B illustrate the comparison of the two inspection techniques, with FIG. 6A showing inspection using the rendered mask contours resulting in detection of zero errors in the rectilinear region and detection of approximately 593 errors in the curvilinear region, while FIG. 6B showing inspection using the PoR method resulting in detection of zero errors in the rectilinear region and detecting massive amount of errors in the curvilinear region, resulting in abortion of the inspection. The use of the fractured/rendered design in the PoR method changed the rendered mask contours so that there were many false detections. Millions of errors were detected using normal production flow and less were detected using simulated mask contours. Corner rounding and line end shortening were not reported with the inventive flow which use rendered mask contour, which reduced turn-around time without compromising or reducing sensitivity to flush out real defects. The techniques described herein are not only applicable for reducing false defects but are critical to identifying, properly classifying and filtering real defects caused by mask writer and process resolution capabilities.

In accordance with exemplary embodiments of the present invention, a calibrated mask simulation step is introduced into the inspection process that directly captures the mask manufacturing and the effect the mask manufacturing has on the original design database. This simulation step may be applied in advance as a pre-step or can be embedded directly on the inspection tool. The concept of applying a calibrated mask process simulation pre-step can be used in any measurement or inspection process that relies on a design database reference image. For example, certain CD SEM measurement tools also rely on database reference images to produce a result.

As will be appreciated by one skilled in the art, the preferred embodiment may be implemented as a method, a data processing system, or a computer program product. Accordingly, the preferred embodiment may take the form of an entirely hardware embodiment, an entirely software embodiment, or an embodiment combining software and hardware aspects. Furthermore, implementations of the preferred embodiment may take the form of a computer program product on a computer-readable storage medium having computer-readable program instructions (e.g., computer software) embodied in the storage medium. More particularly, implementations of the preferred embodiments may take the form of web-implemented computer software. Any suitable computer-readable storage medium may be utilized including hard disks, CD-ROMs, optical storage devices, or magnetic storage devices.

The preferred embodiments according to the present invention are described below with reference to block diagrams and flowchart illustrations of methods, apparatuses (i.e., systems) and computer program products according to an embodiment of the invention. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

Now that embodiments of the present invention have been shown and described in detail, various modifications and improvements thereon will become readily apparent to those skilled in the art. Accordingly, the spirit and scope of the present invention is to be construed broadly and not limited by the foregoing specification.

1. A method comprising:
(A) rendering a simulated photomask design database contour based on starting photomask design and photomask manufacturing data;
(B) manufacturing a photomask based on the photomask design data; and
(C) performing an inspection for photomask defects by comparing the rendered simulated photomask contour with the manufactured photomask.

2. The method of claim 1, wherein step (A) comprises:
1) generating a photomask manufacturing process model based on the photomask design data, critical structures of the photomask and high resolution mask images of the critical structures, the photomask process model comprising data associated with simulated photomask contours; and
2) applying the photomask manufacturing process model to the design database to create a simulated rendering of the design database.

3. The method of claim 2, wherein step (A)(1) is performed using a model generated by an Electronic Design Automation (EDA) tool or with a model generation engine purpose built for producing accurate mask model contours.

4. The method of claim 1, wherein the photomask comprises curvilinear regions.

5. The method of claim 1, wherein the photomask comprises rectilinear regions.

6. The method of claim 1, further comprising correcting the photomask defects by modifying the rendered simulated photomask contour.

7. A method of manufacturing a photomask comprising the method of claim 1.

8. A system comprising:
one or more computer processors; and
non-transitory computer-readable memory having stored thereon instructions which, when executed by the one or more computer processors, cause the one or more computer processors to carry out a method comprising:
(A) rendering a simulated photomask contour based on photomask design data;
(B) manufacturing a photomask based on the photomask design data; and
(C) performing an inspection for photomask defects by comparing the rendered simulated photomask contour with the manufactured photomask.

9. The system of claim 8, wherein step (A) comprises:
1) generating a photomask process model based on the photomask design data, critical structures of the photomask and known scanning electron microscope (SEM) images of the critical structures, the photomask process model comprising data associated with simulated photomask contours;
2) refining the mask process model by comparing the data associated with the simulated photomask contours with a singular or stitched together image of the SEM images; and
3) performing a forward simulation of the simulated photomask contours to render the photomask contours.

10. The system of claim 9, wherein step (A)(1) is performed using an Electronic Design Automation (EDA) tool.

11. The system of claim 8, wherein the photomask comprises curvilinear regions.

12. The method of claim 8, wherein the photomask comprises rectilinear regions.

13. The method of claim 8, further comprising the step of correcting the photomask defects by modifying the rendered simulated photomask contours.
